(19) United States
(12) Patent Application Publication
(10) Pub. No.: US 2009/0141505 A1
(43) Pub. Date: Jun. 4, 2009

(54) WHITE HEAT-HARDENING RESIN COMPOSITION, HARDENED MATERIAL, PRINTED-WIRING BOARD AND REFLECTION BOARD FOR LIGHT EMITTING DEVICE

(75) Inventors: Shigeru USHIKI, Saitama (JP); Yoshikazu Daigo, Saitama (JP)

Correspondence Address: DITTHAVONG MORI & STEINER, P.C., 918 Prince St., Alexandria, VA, 22314, US

(73) Assignee: TAIYO INK MFG., CO,. LTD., Tokyo (JP)

(21) Appl. No.: 12/324,133

(22) Filed: Nov. 26, 2008

(30) Foreign Application Priority Data
Nov. 30, 2007 (JP) 2007-311549

(51) Int. Cl. C08L 71/10; H05K 1/00; F21V 7/00

(52) U.S. Cl. 362/341; 524/611; 174/250

(57) ABSTRACT

A white heat-hardening resin composition includes rutile-type titanium oxide and a heat-hardening resin.

### CROSS-REFERENCE TO RELATED APPLICATIONS

The present application claims priority under 35 U.S.C. §119 to Japanese Patent Application No. 2007-311549, filed Nov. 30, 2007. The contents of this application are incorporated herein by reference in their entirety.

### BACKGROUND OF THE INVENTION

1. Field of the Invention

The present invention relates to a white heat-hardening resin composition, a hardened material, a printed-wiring board including the hardened material, and a reflection board for light emitting devices including the hardened material.

2. Discussion of the Background

In printed-wiring boards, there have been recently increased applications of use that LED emitting by a low electric power in a backlight of liquid crystal display for mobile terminals, personal computers and televisions and the like, or a light source of lighting equipment is directly mounted. See the paragraphs [0002] to [0007] of Japanese Unexamined Patent Publication No. 2007-249148. The contents of Japanese Unexamined Patent Publication No. 2007-249148 are incorporated herein by reference in their entirety.

In this case, regarding an insulation film coated and formed as a protective film in a printed-wiring board, in addition to characteristics such as solvent resistance, hardness, solder resistance and electrical insulating properties generally required in a solder resist film, an excellent light reflectivity capable of utilizing emission of LED effectively has been desired.

However, a white solder resist composition conventionally used has had a problem that oxidation of resin due to light and heat irradiated by LED proceeds to turn yellow, lowering reflectivity with time.

### SUMMARY OF THE INVENTION

According to one aspect of the present invention, a white heat-hardening resin composition includes rutile-type titanium oxide and a heat-hardening resin.

According to another aspect of the present invention, a hardened material includes a substrate and a white hardened resin. The white hardened resin is provided on the substrate in such a manner that a white heat-hardening resin composition coated on the substrate is hardened to be the white hardened resin. The white heat-hardening resin composition includes rutile-type titanium oxide and a heat-hardening resin.

According to further aspect of the present invention, a printed-wiring board includes an insulation layer which includes the hardened material as described above.

According to the other aspect of the present invention, a reflection board for light emitting device includes the hardened material as described above.

A white heat-hardening resin composition according to an embodiment of the present invention can maintain a high reflectivity for a long period of time, so in the case that it is used as an insulation layer in a printed-wiring board mounted with light emitting devices such as LED, it can utilize light of LED and the like efficiently, which can raise lighting intensity as a whole for a long time. The white heat-hardening resin composition according to the present invention is not limited to a printed-wiring board, and alternatively used as components required with a high reflectivity, for example, as a reflection board for light emitting devices such as EL and LED.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a top plan view schematically showing a printed-wiring board mounted with light emitting devices;

FIG. 2 is a side view schematically showing a printed-wiring board mounted with light emitting devices;

FIGS. 3A-3D are schematic diagrams of a part of production process for a printed-wiring board mounted with light emitting devices as a pattern diagram, and FIGS. 3A and 3B are the top plan views thereof and FIGS. 3C and 3D are the side views thereof;

FIG. 4 is a top plan view schematically showing a reflection board for light emitting device; and

FIG. 5 is a side view schematically showing a reflection board for light emitting device.

### DESCRIPTION OF THE EMBODIMENTS

Embodiments will now be described with reference to the accompanying drawings, wherein like reference numerals designate corresponding or identical elements throughout the various drawings.

The white heat-hardening resin composition according to an embodiment of the present invention contains (A) rutile-type titanium oxide and (B) a heat-hardening resin.

In the embodiment of the present invention, as a white pigment, it is characterized by using rutile-type titanium oxide (A). Anatase-type titanium oxide of the same titanium oxide is high in whiteness compared with rutile-type titanium oxide, and often used as a white pigment. However, since anatase-type titanium oxide has a photocatalytic activity, change in color of a resin in an insulating resin composition is sometimes caused by a light irradiated from LED in particular. In contrast to this, rutile-type titanium oxide has almost no photoactivation although whiteness is somewhat inferior to the anatase-type, so deterioration (yellowing) of a resin resulting from photoactivation of titanium oxide is markedly suppressed, showing a stability to heat. Therefore, in the case that it is used as a white pigment in an insulation layer of a printed-wiring board mounted with LED, a high reflectivity can be maintained for a long time.

In the case that the white heat-hardening resin composition according to the embodiment of the present invention is used in a reflection board for light emitting devices such as EL and LED, the lowering of reflectivity with time and coloring due to deterioration are suppressed, so that a high reflectivity can be maintained for a long time.

As rutile-type titanium oxide (A), one commonly known can be used. As the production method of rutile-type titanium oxide, there are two kinds of sulfuric acid method and chlorine method, in the embodiment of the present invention, one produced by either production method can suitably be used. Here, the sulfuric acid method uses ilmenite ore or titanium slag as a raw material, which is dissolved in concentrated sulfuric acid to separate iron as iron sulfate, and the solution is hydrolyzed to obtain precipitate of hydroxide, and this is fired at high temperature to take out rutile-type titanium oxide. On the other hand, the chlorine method uses synthetic rutile or natural rutile as a raw material, which is reacted with chlorine gas and carbon at a high temperature of 1000° C. to synthesize titanium tetrachloride, and this is oxidized to take out rutile-type titanium oxide. Among these, rutile-type titanium oxide produced by the chlorine method is remarkable in suppression effect on deterioration (yellowing) of resin particularly due to heat, so it is suitably used in the embodiment of the present invention.

As rutile-type titanium oxide commercially available, for example, there are Tipaque R-820, Tipaque R-830, Tipaque R-930, Tipaque R-550, Tipaque R-630, Tipaque R-680, Tipaque R-670, Tipaque R-680, Tipaque R-670, Tipaque R-780, Tipaque R-850, Tipaque CR-50, Tipaque CR-57, Tipaque CR-80, Tipaque CR-90, Tipaque CR-93, Tipaqueb CR-95, Tipaque CR-97, Tipaque CR-60, Tipaque CR-63, Tipaque CR-67, Tipaque CR-58, Tipaque CR-85 and Tipaque UT771 (manufactured by Ishihara Sangyo Kaisha Ltd.), Ti-Pure R-100, Ti-Pure R-101, Ti-Pure R-102, Ti-Pure R-103, Ti-Pure R-104, Ti-Pure R-105, Ti-Pure R-108, Ti-Pure R-900, Ti-Pure R-902, Ti-Pure R-960, Ti-Pure R-706 and Ti-Pure R-931 (manufactured by DuPont Corporation), R-25, R-21, R-32, R-7E, R-5N, R-61N, R-62N, R-42, R-45, R-44, R-49S, GTR-100, GTR-300, D-918, TCR-29, TCR-52 and FTR-700 (manufactured by Sakai Chemical Industry Co., Ltd.) and the like can be used.

Among these, Tipaque CR-50, Tipaque CR-57, Tipaque CR-80, Tipaque CR-90, Tipaque CR-93, Tipaqueb CR-95, Tipaque CR-97, Tipaque CR-60, Tipaque CR-63, Tipaque CR-67, Tipaque CR-58, Tipaque CR-85 and Tipaque UT771 (manufactured by Ishihara Sangyo Kaisha Ltd.), Ti-Pure R-100, Ti-Pure R-101, Ti-Pure R-102, Ti-Pure R-103, Ti-Pure R-104, Ti-Pure R-105, Ti-Pure R-108, Ti-Pure R-900, Ti-Pure R-902, Ti-Pure R-960, Ti-Pure R-706 and Ti-Pure R-931 (manufactured by DuPont Corporation) and the like produced by the chlorine method can be more preferably used.

The compounding ratio of rutile-type titanium oxide (A) is preferably 30 to 600 parts by mass, and more preferably 50 to 500 parts by mass, relative to 100 parts by mass of heat-hardening resin (B). When the compounding ratio of the rutile-type titanium oxide (A) exceeds 600 parts by mass, dispersibility of the rutile-type titanium oxide (A) deteriorates so that dispersion becomes bad, which is not preferable. On the other hand, when the compounding ratio of the rutile-type titanium oxide (A) is less than 30 parts by mass, it is not preferable because hiding power becomes small and it becomes difficult to obtain an insulation film of high reflectivity.

Next, (B) a heat-hardening resin is explained.

As the heat-hardening resin (B) used in the embodiment of the present invention, it may be a resin showing electrical insulating properties after being hardened by heating, for example, there are listed an epoxy compound, an oxetane compound, a melamine resin, a silicone resin and the like. In particular, (B-1) an epoxy compound and/or (B-2) an oxetane compound are preferably used in the embodiment of the present invention.

As the epoxy resin (B-1), commonly known and used compounds having at least one epoxy group can be used, above all, compounds having two or more epoxy groups are preferable. For example, there are listed monoepoxy compounds such as butyl glycidyl ether, phenyl glycidyl ether and glycidyl (meth)acrylate; and compounds having two or more epoxy groups in a molecule such as a bisphenol A type epoxy resin, bisphenol S type epoxy resin, bisphenol F type epoxy resin, phenol novolac type epoxy resin, cresol novolac type epoxy resin, alicyclic epoxy resin, trimethylolpropane polyglycidyl ether, phenyl-1,3-diglycidyl ether, biphenyl-4,4′-diglycidyl ether, 1,6-hexanediol diglycidyl ether, diglycidyl ether of ethylene glycol or propylene glycol, sorbitol polyglycidyl ether, tris(2,3-epoxypropyl)isocyanurate and triglycidyl tris(2-hydroxyethyl)isocyanurate.

These can be used alone or in combination of two kinds or more upon request of improvement on characteristics of coated film.

Next, the oxetane compound (B-2) is explained.

As a concrete example of oxetane compound (B-2) containing an oxetane ring expressed by the following general formula (I),

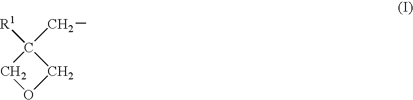

(wherein R1 represents a hydrogen atom or an alkyl group having carbon numbers of 1 to 6.)

there are listed 3-ethyl-3-hydroxymethyloxetane (trade name OXT-101 manufactured by Toagosei Co., Ltd.),

3-ethyl-3-(phenoxymethyl)oxetane (trade name OXT-211 manufactured by Toagosei Co., Ltd.), 3-ethyl-3-(2-ethylhexyloxymethyl)oxetane (trade name OXT-212 manufactured by Toagosei Co., Ltd.),
1,4-bis{[(3-ethyl-3-oxetany)methoxy]methyl}benzene (trade name OXT-121 manufactured by Toagosei Co., Ltd.),
bis(3-ethyl-3-oxetanylmethyl)ether (trade name OXT-221 manufactured by Toagosei Co., Ltd.) and the like. Further, a phenol novolac type oxetane compound and the like are listed.

The oxetane compound can be used in concomitant use of the epoxy compound or alone.

The oxetan compound (B-2) can be used in combination of the epoxy compound (B-1) or alone.

In the white heat-hardening resin composition according to the embodiment of the present invention, (C-1) a hardener and/or (C-2) a curing catalyst can further be added.

As the hardener (C-1), there are listed a multifunctional phenol compound, polycarboxylic acid and its acid anhydride, aliphatic or aromatic, primary or secondary amine, polyamide resin, polymercapto compound and the like. Among these, a multifunctional phenol compound, polycarboxylic acid and its acid anhydride are preferably used from the points of workability and insulation properties.

Among these hardeners (C-1), a multifunctional phenol compound may be a compound having two or more phenolic hydroxyl groups in a molecule, and can use commonly known and used ones. Specifically, there are listed a phenol novolac resin, a cresol novolac resin, bisphenol A, allylated bisphenol A, bisphenol F, a novolac resin of bisphenol A, a vinylphenol copolymerized resin and the like, in particular, a phenol novolac resin is preferable because reactivity is high and the effect of enhancing heat resistance is also high. Such multifunctional phenol compound undergoes addition reaction with the epoxy compound (B-1) and/or oxetane compound (B-2) under the presence of a suitable curing catalyst.

The polycarboxylic acid and its acid anhydride are a compound having two or more carboxylic groups in a molecule and its acid anhydride, for example, copolymer of (meth) acrylic acid, copolymer of maleic anhydride, condensate of dibasic acid and the like are listed. As the commercial product, there are listed Joncryl (name of product group) manufactured by BASF Corporation, SMA resin (name of product group) manufactured by Sartmer Company Ltd., polyazelaic acid anhydride manufactured by New Japan Chemical Co., Ltd. and the like.

The compounding ratio of the hardener (C-1) may be a quantitative ratio ordinarily used, and is preferably 1 to 200 parts by mass, and more preferably 10 to 100 parts by mass, relative to 100 parts by mass of heat-hardening resin (B), for example, of the epoxy compound (B-1) and/or the oxetan compound (B-2).

Next, a curing catalyst (C-2) is explained.

This curing catalyst (C-2) is a compound which can be a curing catalyst in a reaction of an epoxy compound (B-1) and/or an oxetane compound (B-2) with the hardener (C-1), or a compound which becomes a polymerization catalyst when no hardener is used, for example, there are listed tertiary amine, tertiary amine salt, quaternary onium salt, tertiary phosphine, crown ether complex, phosphonium ylide and the like, arbitrarily from these, they can be used alone or in combination of two kinds or more thereof.

Among these, as preferable ones, there are listed imidazoles such as trade names 2E4MZ, C11Z, C17Z and 2PZ; AZINE compounds of imidazole such as trade names 2MZ-A and 2E4MZ-A; isocyanurate of imidazole such as trade names 2MZ-OK and 2PZ-OK; and hydroxymethyl substance of imidazole such as trade names 2PHZ and 2P4 MHZ (the is all trade names of Shikoku Chemicals Corporation), dicyandiamide and the derivatives, melamine and the derivatives, diaminomaleonitrile and the derivatives, amines such as diethylenetriamine, triethylenetetramine, tetraethylenepentamine, bis(hexamethylene)triamine, triethanolamine, diaminodiphenylmethane and organic acid dihydrazide, 1,8-diazabicyclo[5,4,0]undecene-7 (trade name DBU, manufactured by San-Apro Ltd.),

3,9-bis(3-aminopropyl)-2,4,8,10-tetraoxaspiro[5,5]undecane (trade name ATU, manufactured by Ajinomoto Co., Ltd.) or organic phosphine compounds such as triphenyl phosphine, tricyclohexyl phosphine, tributyl phosphine and methyl diphenyl phosphine.

The compounding ratio of the curing catalysts (C-2) may be a quantitative ratio ordinarily used, and is preferably 0.05 to 10 parts by mass, and more preferably 0.1 to 3 parts by mass, relative to 100 parts by mass of heat-hardening resin (B), for example, of the epoxy compound (B-1) and/or the oxetan compound (B-2).

The white heat-hardening resin composition according to the embodiment of the present invention can contain an organic solvent used for preparation of composition and adjustment of viscosity. As the organic solvent, for example, there can be used ketones such as methyl ethyl ketone and cyclohexanone; aromatic hydrocarbons such as toluene, xylene and tetramethylbenzene; glycol ethers such as cellosolve, methyl cellosolve, butyl cellosolve, carbitol, methyl carbitol, butyl carbitol, propylene glycol monomethyl ether, dipropylene glycol monomethyl ether, dipropylene glycol diethyl ether and tripropylene glycol monomethyl ether; esters such as ethyl acetate, butyl acetate, butyl lactate, cellosolve acetate, butyl cellosolve acetate, carbitol acetate, butyl carbitol acetate, propylene glycol monomethyl ether acetate, dipropylene glycol monomethyl ether acetate and propylene carbonate; aliphatic hydrocarbons such as octane and decane; and petroleum based solvents such as petroleum ether, petroleum naphtha and solvent naphtha. These organic solvents can be used alone or in combination of two kinds or more thereof.

The white heat-hardening resin composition according to the embodiment of the present invention can further compound, if necessary, commonly known and used thickeners such as finely-powdered silica, organic bentonite and montmorillonite; and commonly known and used additives including defoaming agents and/or leveling agents of silicone type, fluorine type and polymer type etc., silane coupling agents of imidazole type, thiazole type and triazole type etc., and can compound coloring agents in a range not damaging whiteness of the heat-hardening resin composition according to the embodiment of the present invention.

The white heat-hardening resin composition according to the embodiment of the present invention is coated on a substrate by a method such as screen printing method after adjusting its viscosity to be suitable for a coating method with the solvent. After coating, a hardened coat can be obtained through thermal hardening by heating at a temperature of 140° C. to 180° C. for example.

The white heat-hardening resin composition according to the present invention is not limited to a printed-wiring board, and alternatively used as components required with a high reflectivity, for example, as a reflection board for light emitting devices such as EL and LED.

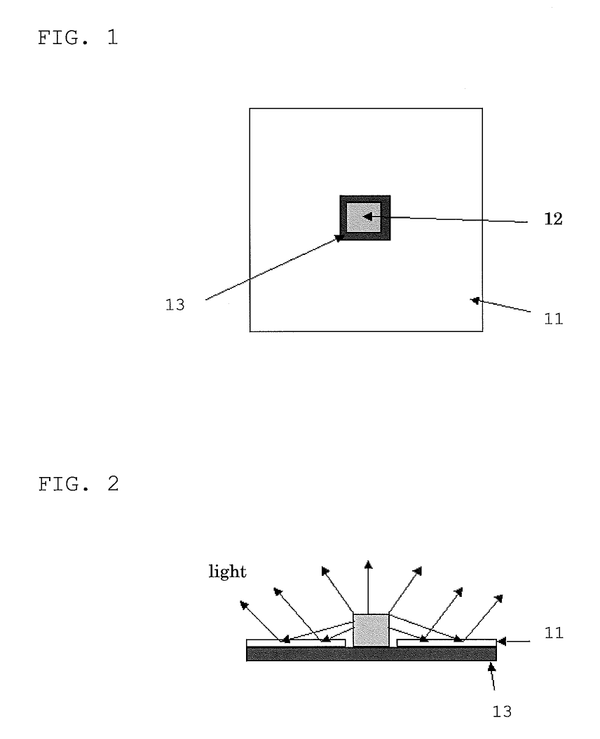

FIGS. 1 to 5 show examples of use when the white heat-hardening resin composition is used to a reflection board for light emitting devices such as LED and EL.

FIGS. 1 and 2 are a mode that a white heat-hardening resin composition itself, which is an insulation material of the outermost layer of a printed-wiring board mounted with light emitting devices, is used as a white resist material with a high reflectivity.

FIG. 1 is a top plan view of the printed-wiring board. FIG. 2 is a side view of the printed-wiring board.

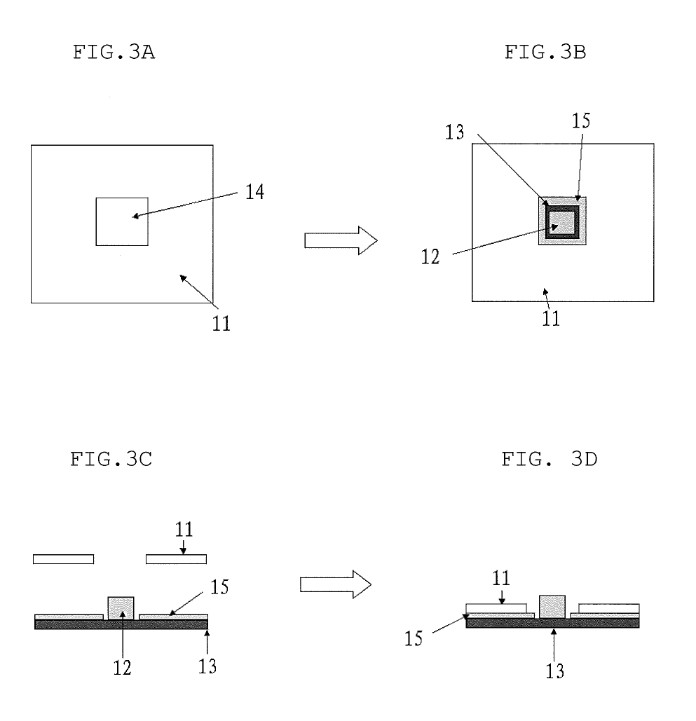

FIG. 3 shows the following processes.

Namely, as a solder resist material for directly coating on a printed-wiring board, colored one such as green or white is used, and the solder resist layer is processed in such manner that a light emitting device mounted on a printed-wiring board is bored. A white heat-hardening resin composition is coated on a plastic or metal sheet, and the plastic or sheet is processed in such manner that the part corresponding to a light emitting device is bored in a similar way to that of the solder resist layer (see FIGS. 3A and 3C).

The processed plastic or sheet is thus overlapped on a printed-wiring board (see FIGS. 3B and 3D).

As a result, it seemed that a white heat-hardening resin composition with a high reflectivity is formed on the outermost layer.

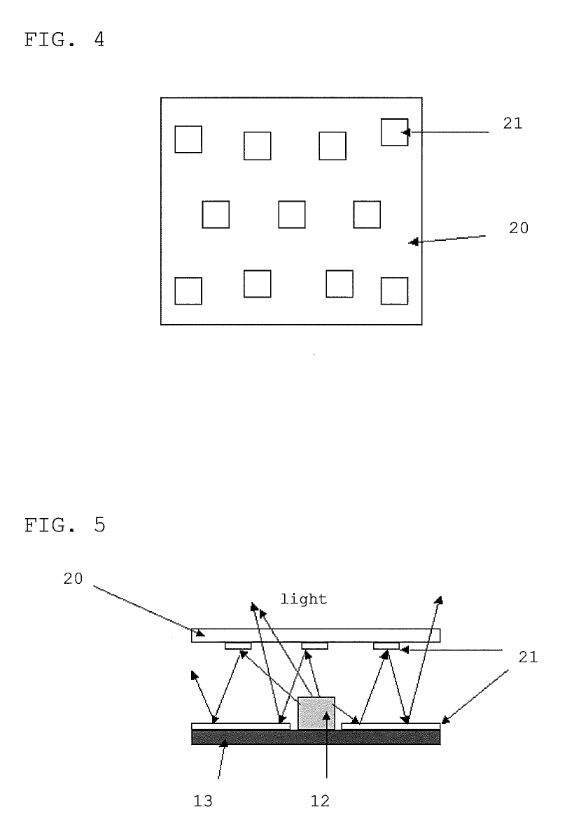

FIGS. 4 and 5 show a reflection board for light emitting devices such as LED and EL formed by the following process. Namely, a reflection board for light emitting device shown in FIGS. 1 and 2, and FIGS. 3A-3D is first formed. Then, a reflection board in which a white heat-hardening resin composition was coated in a specific pattern on a transparent material such as glass, polyethylene terephthalate and polyethylene naphthalate is produced. The transparent substrate is overlapped on the reflection board for light emitting device. By the above mode, a uniform lighting intensity can be achieved by diffusion of light to be taken.

Additionally, in any mode described above, a white heat-hardening resin composition (hardened material) is supposed to be exposed to the light and heat irradiated from a light emitting device, which is a deterioration factor such as yellowing. Even in such situation, the white heat-hardening resin composition and its hardened material according to the embodiment of the present invention can hold a high reflectivity for a long period of time.

### EXAMPLES

Next, the embodiment of the present invention will be specifically explained by showing Examples, but it goes without saying that the present invention is not limited to the following Examples.

Each component was mixed by a three roll mill in accordance with Table 1, and each heat-hardening resin composition (Composition Examples 1 through 6) was obtained. Numbers in the tables represent part by mass.

TABLE 1

| | (Composition Example) | | | | | |
|---|---|---|---|---|---|---|
| | Example 1 | Example 2 | Example 3 | Example 4 | Example 5 | Example 6 |
| Bisphenol epoxy resin | 500 | 500 | 500 | 500 | 500 | 500 |
| (B-1-1)*¹ | | | | | | |
| Bisphenol epoxy resin | 500 | 500 | 500 | 500 | 500 | 500 |
| (B-1-2)*² | | | | | | |
| Curing catalyst (C-2)*³ | 30 | 30 | 30 | 30 | 30 | 30 |
| Rutile-type titanium oxide | 1000 | — | — | — | — | — |
| (A-1)*⁴ | | | | | | |
| Rutile-type titanium oxide | — | 1000 | — | — | — | — |
| (A-2)*⁵ | | | | | | |
| Rutile-type titanium oxide | — | — | 1000 | — | — | — |
| (A-3)*⁶ | | | | | | |
| Rutile-type titanium oxide | — | — | — | 1000 | — | — |
| (A-4)*⁷ | | | | | | |
| Anatase-type titanium oxide*⁸ | — | — | — | — | 1000 | — |
| Anatase-type titanium oxide*⁹ | — | — | — | — | — | 1000 |
| Organic bentonite*¹⁰ | 10 | 10 | 10 | 10 | 10 | 10 |
| Defoaming agent*¹¹ | 5 | 5 | 5 | 5 | 5 | 5 |
| Organic solvent DPM*¹² | 150 | 150 | 150 | 150 | 150 | 150 |

(Remark)
*¹Epicoat 828: manufactured by Japan Epoxy Resins Co., Ltd.
*²Epicoat 807: manufactured by Japan Epoxy Resins Co., Ltd.
*³2MZ-A (2,4-diamino-6-[2′-methylimidazolyl-(1′)]-ethyl-s-triazine), manufactured by Shikoku Chemicals Corporation
*⁴Tipaque CR-90 (Chlorine-method rutile-type titanium oxide): manufactured by Ishihara Sangyo Kaisha Ltd.
*⁵R-62N (Sulfuric acid-method rutile-type titanium oxide): manufactured by Sakai Chemical Industry Co., Ltd.
*⁶Tipaque C-90 (Sulfuric acid-method rutile-type titanium oxide): manufactured by Ishihara Sangyo Kaisha Ltd.
*⁷Tipaque CR-58 (Chlorin-method rutile-type titanium oxide): manufactured by Ishihara Sangyo Kaisha Ltd.
*⁸A-190 (Anatase-type titanium oxide): manufactured by Sakai Chemical Industry Co., Ltd.
*⁹Tipaque A-220 (Anatase-type titanium oxide): manufactured by Ishihara Sangyo Kaisha Ltd.
*¹⁰Bentone 38: manufactured by Elemetis Inc,
*¹¹BYK-057: manufactured by Big Chemi Co., Ltd.
*¹²Dipropylene glycol monomethyl ether

### Performance Evaluation

### (Production of Board for Evaluating Coated Film Characteristics)

Heat-hardening resin compositions of Examples 1 to 6 were each pattern-printed on a FR-4 substrate of flat copper by screen printing for a dried coated film to be about 20 μm, followed by heating at 150° C. for 60 minutes to harden, and a test piece was obtained. The test piece obtained was evaluated for the characteristics as follows.

### (1) Light Resistance

For each test piece, using a color-difference meter, CR-400 manufactured by Minolta Co., Ltd., the initial value of Y value in XYZ color coordinate system, and the initial values of L*, a* and b* in L*, a* and b* color coordinate system were measured. Thereafter, each test piece was deteriorated at an accelerating rate by irradiating light of 150 J/cm² in an UV conveyer furnace (output 150 W/cm, metal halide lamp, cold mirror), again, each value was measured using a color-difference meter CR-400 manufactured by Minolta Co., Ltd., evaluation was made by the change of Y value and ΔE*ab. The result is shown together with the evaluation result on change in color by naked eye in Table 2.

### (2) Heat Resistance

For each test piece, using a color-difference meter CR-400 manufactured by Minolta Co., Ltd., the initial value of Y value in XYZ color coordinate system, and the initial values of L*, a* and b* in L*, a* and b* color coordinate system were measured. Thereafter, each test piece was deteriorated at an accelerating rate by leaving it in a hot air circular drying furnace at 150° C. for 50 hours, again, each value was measured using a color-difference meter, CR-400 manufactured by Minolta Co., Ltd., evaluation was made by the change of Y value and ΔE*ab. The result is shown together with the evaluation result on change in color by naked eye in Table 2.

TABLE 2

| | | (Composition Example) | | | | | |
|---|---|---|---|---|---|---|---|
| | | Example 1 | Example 2 | Example 3 | Example 4 | Example 5 | Example 6 |
| Y (Initial value) | | 77.3 | 76.0 | 82.1 | 80.9 | 78.7 | 81.1 |
| (1) Light | Y | 76.4 | 74.3 | 81 | 79.8 | 63.5 | 64.7 |
| resistance | ΔE*ab | 1 | 1.1 | 0.9 | 0.9 | 4.6 | 6.5 |
| | Visual | ◯◯ | ◯◯ | ◯◯ | ◯◯ | X | X |
| | evaluation | | | | | | |
| (2) Heat | Y | 74.2 | 73.1 | 78.5 | 77.3 | 67.6 | 68.9 |
| resistance | ΔE*ab | 1.5 | 1.7 | 0.9 | 0.9 | 2.5 | 2.2 |
| | Visual | ◯ | ◯ | ◯◯ | ◯◯ | Δ | Δ |
| | evaluation | | | | | | |

Y value is a value of Y in XYZ color coordinate system, and the larger the numeric value is, the higher the reflectivity shows. ΔE*ab is the difference calculated between the initial value in L*, a* and b* color coordinate system and the value after accelerated deterioration, and the larger the numeric value is, the larger the change in color shows. The calculation formula of ΔE*ab is as follows.

ΔE*ab=((L*2−L*1)²+((a*2−a*1)²+((b*2−b*1)²)^{0.5}

wherein L*1, a*1 and b*1 represent initial values of L*, a* and b*, respectively, L*2, a*2 and b*2 represent values of L*, a* and b* after accelerated deterioration, respectively.

Evaluation criteria of visual evaluation are as follows.

oo: there is no change in color at all.

o: there is almost no change in color.

Δ: there is somewhat change in color.

x: there is change in color

### (3) Solvent Resistance

Each test piece was immersed in propylene glycol monomethyl ether acetate for 30 minutes, and dried, then change in color was observed by naked eye, further, presence of peeling by tape peel was confirmed. Evaluation criteria are as follows.

o: there is neither peeling nor change in color.

x: there is peeling or change in color.

The result is shown in Table 3.

### (4) Solder Heat Resistance

The presence of peeling of coated film was confirmed as follows: each test piece coated with rosin-based flux was flowed in a solder bath previously set at 260° C., washed with propylene glycol monomethyl ether acetate and dried, then, a peel test was done using a cellophane adhesive tape, and presence of peeling of coated film was confirmed. Evaluation criteria are as follows.

o: there is no peeling.

x: there is peeling.

The result is shown in Table 3.

### (5) Pencil Hardness

Tips of pencils of B to 9H being sharpened in a flat tip were pressed down on each test piece at an angle of 45°, and hardness of the hardest pencil that coated film was not peeled was recorded. The result is shown in Table 3.

### (6) Electrical Insulating Properties

Using a FR-4 substrate that comb-shaped electrodes of B pattern of IPC specification were formed in place of the copper foil substrate, it was pattern-printed by screen printing for a dried coated film to be about 20 μm in the same manner as described above, followed by heating at 150° C. for 60 minutes to harden, and a test piece was obtained. The insulation resistance value between the electrodes of each test piece was measured at an applied voltage of 500 V. The result is shown in Table 3.

TABLE 3

| | (Composition Example) | | | | | |
|---|---|---|---|---|---|---|
| | Example 1 | Example 2 | Example 3 | Example 4 | Example 5 | Example 6 |
| (3) Solvent resistance | ◯ | ◯ | ◯ | ◯ | ◯ | ◯ |
| (4) Solder heat resistance | ◯ | ◯ | ◯ | ◯ | ◯ | ◯ |
| (5) Pencil hardness | 6H | 6H | 6H | 6H | 6H | 6H |
| (6) Electrical insulating | 10¹³ | 10¹³ | 10¹³ | 10¹³ | 10¹³ | 10¹³ |
| properties | | | | | | |

As is clear from the results shown in Tables 2 and 3, it is known that the white heat-hardening resin composition according to the embodiment of the present invention satisfies various characteristics generally required for an insulation layer of a printed-wiring board, and maintains a high reflectivity and suppresses change in color after accelerated deterioration by light and heat. In particular, light resistance is markedly improved compared with the case of using anatase-type titanium oxide.

Since the white heat-hardening resin composition according to the embodiment of the present invention has a characteristic for maintaining a high reflectivity generally required as a reflection board for light emitting device and suffering no light deterioration and heat deterioration and stable for a long period of time, when it is applied to a reflection board for light emitting devices such as EL and LED, it is possible to obtain a reflection board for light emitting devices such as EL and LED excellent in maintaining a high reflectivity and suffering no light deterioration and heat deterioration and stable for a long period of time.

Obviously, numerous modifications and variations of the present invention are possible in light of the above teachings. It is therefore to be understood that within the scope of the appended claims, the invention may be practiced otherwise than as specifically described herein.

What is claimed as new and is desired to be secured by Letters Patent of the United States is:

1. A white heat-hardening resin composition comprising:
rutile-type titanium oxide; and
a heat-hardening resin.

2. The white heat-hardening resin composition according to claim 1, wherein a compounding ratio of mass of the rutile-type titanium oxide to mass of the heat-hardening resin is at least about 30 and at most about 600 to 100.

3. The white heat-hardening resin composition according to claim 1, wherein the heat-hardening resin comprises at least one of an epoxy compound and an oxcetane compound.

4. The white heat-hardening resin composition according to claim 1, further comprising at least one of a hardener and a curing catalyst.

5. A hardened material comprising:
a substrate; and
a white hardened resin provided on the substrate in such a manner that a white heat-hardening resin composition coated on the substrate is hardened to be the white hardened resin, the white heat-hardening resin composition comprising:
rutile-type titanium oxide; and
a heat-hardening resin.

6. A printed-wiring board comprising:
an insulation layer comprising:
the hardened material according claim 5.

7. A reflection board for light emitting device, comprising:
the hardened material according claim 5.

8. The reflection board according to claim 7, wherein the reflection board is for electroluminescence.

9. The reflection board according to claim 7, wherein the reflection board is for light emitting diode.
